(19) United States
(12) Patent Application Publication
(10) Pub. No.: US 2011/0267308 A1
(43) Pub. Date: Nov. 3, 2011

(54) Touch screen panel and method for manufacturing the same

(76) Inventors: Mi-Ae Park, Yongin-City (KR); Sung-Ku Kang, Yongin-City (KR)

(21) Appl. No.: 12/929,188

(22) Filed: Jan. 6, 2011

(30) Foreign Application Priority Data
May 3, 2010 (KR) 10-2010-0041394

(51) Int. Cl. G06F 3/041; G06F 3/045; H05K 3/10

(52) U.S. Cl. 345/174; 345/173; 29/846

(57) ABSTRACT

A touch screen panel includes a plurality of first sensing cells arranged in a first direction and a plurality of second sensing cells arranged in a second direction on a display region of a transparent substrate, a connecting unit connecting the second sensing cells to each other, a connecting pattern connecting the first sensing cells to each other, the connecting pattern intersecting the connecting unit, a first insulating layer between the connecting pattern and the connecting unit, and a colored second insulating layer on the connecting pattern.

### BACKGROUND

1. Field

Embodiments relate to a touch screen panel, and more particularly, to a touch screen panel that is formed in an upper portion of a flat panel display device as a unified body.

2. Description of the Related Art

A touch screen panel is an input device that selects contents displayed on a screen, e.g., an image display device, etc., using a person's hand or an object to input commands of a user. The touch screen panel is provided on a front face of the image display device and converts positions directly contacting the person's hand or object into electrical signals. Accordingly, the instruction selected at the contact point is received as an input signal. As the touch screen panel can replace a separate input device that is operated by being connected with the image display device, e.g., a keyboard and a mouse, the use field of the touch screen panel is being expanded gradually.

The touch screen panel may be implemented as a resistive touch screen panel, light sensing touch screen panel, capacitance touch screen panel, and the like. For example, the capacitance touch screen panel converts a contact position into an electrical signal by sensing a change in capacitance at the contact position relative to other positions or a ground electrode. In this case, in order to decide precisely the contact position on the contact surface, the touch screen panel may include sensing patterns, e.g., first sensing patterns (X patterns) connected along a first direction and second sensing patterns (Y patterns) along a second direction.

### SUMMARY

Embodiments are directed to a touch screen panel, which substantially overcomes one or more of the problems due to the limitations and disadvantages of the related art.

It is therefore a feature of an embodiment to provide a touch screen panel and a method for manufacturing the same, in which the touch screen panel exhibits reduced reflectivity of external light.

At least one of the above and other features and advantages may be realized by providing a touch screen panel, including a plurality of first sensing cells arranged in a first direction and a plurality of second sensing cells arranged in a second direction on a display region of a transparent substrate, a connecting unit connecting the second sensing cells to each other, a connecting pattern connecting the first sensing cells to each other, the connecting pattern intersecting the connecting unit, a first insulating layer between the connecting pattern and the connecting unit, and a colored second insulating layer on the connecting pattern.

The first sensing cells, the second sensing cells, and the connecting unit may include a transparent conductive material. The connecting pattern may include a low-resistance metal. The second insulating layer may include a colored photoresist. The touch screen panel may further include a metal pattern in a non-display region of the transparent substrate, the metal pattern being electrically connected to the first sensing cell and the second sensing cell. The colored second insulating layer may be on the metal pattern. The connecting pattern may be between the first insulating layer and the colored second insulating layer. The colored second insulating layer may cover exposed surfaces of the connecting pattern. The colored second insulating layer may completely overlap at least three surfaces of the connecting pattern. The colored second insulating layer may contact the connecting pattern and the first sensing cells.

At least one of the above and other features and advantages may also be realized by providing a method for manufacturing a touch screen panel, including forming a plurality of first sensing cells arranged in a first direction and a plurality of second sensing cells arranged in a second direction on a display region of a transparent substrate, forming a connecting unit connecting the second sensing cells to each other, forming a connecting pattern connecting the first sensing cells to each other, such that the connecting pattern intersects the connecting unit, forming a first insulating layer between the connecting pattern and the connecting unit, and forming a colored second insulating layer on the connecting pattern.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a plan view of an arrangement of sensing patterns in a touch screen panel according to an embodiment;

FIG. 2 illustrates a cross-sectional view along line I-I′ of FIG. 1; and

FIGS. 3A to 3D illustrate plan views and cross-sectional views of stages in a method for manufacturing a touch screen panel according to an embodiment.

### DETAILED DESCRIPTION

Korean Patent Application No. 10-2010-0041394, filed on May 3, 2010, in the Korean Intellectual Property Office, and entitled: “Touch Screen Panel and Method for Manufacturing Thereof” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout

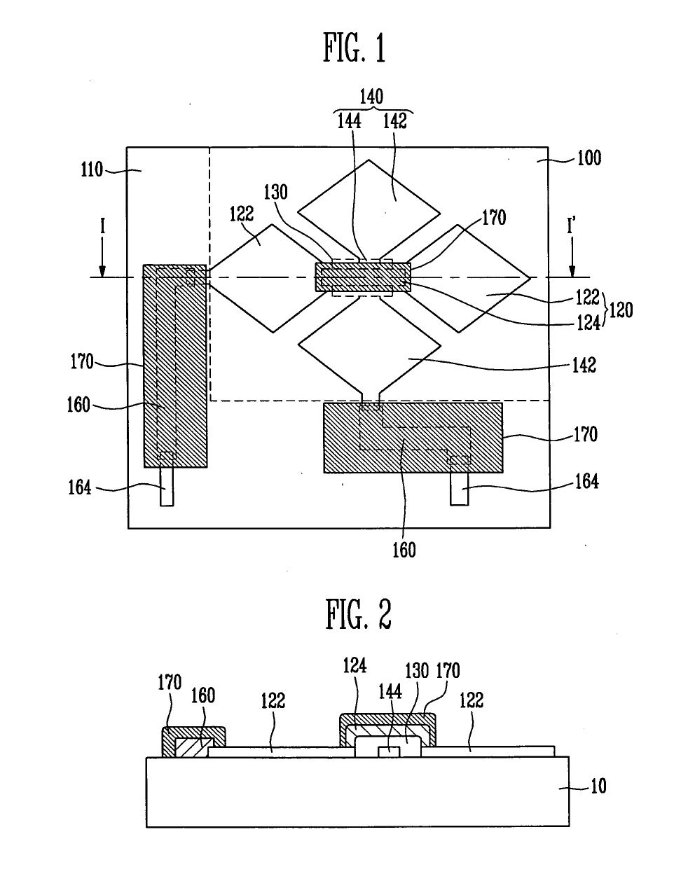

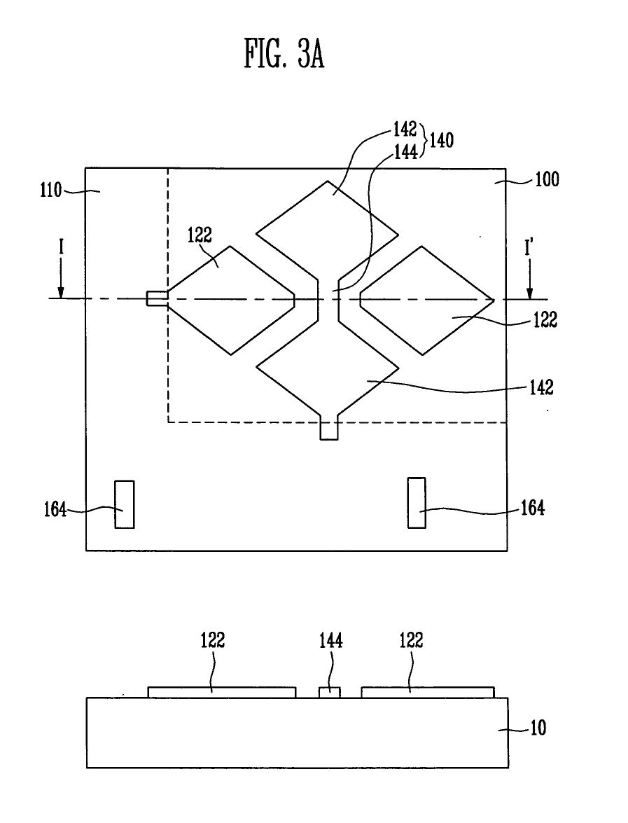

FIG. 1 illustrates a plan view of an arrangement of sensing patterns in a touch screen panel according to an embodiment. FIG. 2 illustrates a cross-sectional view along line I-I′ of FIG. 1.

Referring to FIG. 1 and FIG. 2, sensing patterns according to embodiments may be formed in a display region 100 of a transparent substrate 10. It is noted that the transparent substrate 10 may be divided into the display region 100 and a non-display region 110 formed in an edge portion of the display region 100. The sensing patterns may be alternately disposed, and may include first and second sensing patterns 120, 140 that are formed to connect to each other in a row having the same X coordinate or in a column having the same Y coordinate.

For example, the first sensing patterns 120 may include first sensing cells 122 disposed in a first direction, e.g., in a row having the same X coordinate, and connecting patterns 124 to connect adjacent first sensing cells 122 to each other in the first direction. Similarly, the second sensing patterns 140 may include second sensing cells 142 disposed in a second direction, e.g., in a column having the same Y coordinate, and connecting units 144 to connect adjacent second sensing cells 142 to each other in the second direction.

The first sensing cells 122 and the second sensing cells 142 may be formed in a same layer, and the first and second sensing cells 122, 142 may be formed of a transparent material in order to implement a movement on the touch screen panel. Therefore, the first and second sensing cells 122, 142 may be implemented by a transparent conductive material, i.e., indium-tin-oxide (ITO).

In addition, each sensing cell disposed in the first direction or the second direction may be electrically connected, such that the first sensing cells 122 and the second sensing cells 142 act as a sensing electrode. Therefore, the first sensing cells 122 may be electrically connected to each other by the connecting pattern 124, and the second sensing cells 142 may be electrically connected to each other by the connecting unit 144.

The connecting unit 144 may be formed as a unified body with the second sensing cells 142. In other words, the connecting unit 144 may be formed integrally with the second sensing cells 142, so that adjacent sensing cells 142 may all be connected through the connecting unit 144. Therefore, the connecting unit 144 may be formed of the same transparent conductive material as the second sensing cells 142. The second sensing cells 142, the connecting units 144, and the first sensing cells 122 may be formed in a same layer.

In contrast, the connecting pattern 124 may be formed separately from the first sensing cells 122, e.g., the connecting pattern 124 may be formed of a different material than the first sensing cells 122, while electrically connecting adjacent first sensing cells 122. The connecting patterns 124 may intersect with the connecting unit 144, and may be formed in a different layer than the first and second sensing cells 122, 142 in order to avoid a short. For example, the connecting pattern 124 may be formed in an upper layer of the first and the second sensing cells 122, 142, i.e., the first sensing cells 122 may be between the transparent substrate 10 and the connecting patterns 124.

The connecting patterns 124 according to an embodiment may be made of a low-resistive metal. For example, the connecting patterns 124 may be formed of a same material as a metal pattern 160 that supplies a signal sensed by the sensing cells to a driving circuit (not shown). The metal pattern 160 may be formed in the non-display region 110 adjacent to an end of the display region 100 having the first and the second sensing cells 122, 142, and may be electrically connected to the first and/or second sensing cell 122, 142 to supply the signal sensed by the sensing cells 122, 142 to the driving circuit (not shown). In this regard, it is noted that the region having a plurality of the sensing patterns 120, 140 is the display region 100 that detects a touch position by displaying the image, and the region having the metal patterns 160 electrically connected with the sensing cells 120, 140 is the non-display region 110 included in the edge portion of the display region 100.

The connecting patterns 124 and the metal pattern 160 may be formed in a same layer through the same process. Therefore, a number of processes and the manufacturing time may be reduced because an additional, e.g., a separate, mask process that forms the connecting patterns 124 may not be needed. In addition, a charge flow in the connecting pattern 124 of the first sensing cells 122 may be smooth. Therefore, the sensing sensitivity of the first sensing cells 122 may be improved by implementing the connecting pattern 124 that connects the first sensing cells 122 to each other as a low-resistive metal, e.g., as opposed to a transparent conductive material.

A first insulating layer 130 may be formed between the connecting pattern 124 and the connecting unit 144. The first insulating layer 130 may have an island-shape, and may be positioned to avoid a short between the connecting pattern 124 and the connecting unit 144, which intersect and overlap each other. The first insulating layer 130 may be an inorganic insulating layer made of a transparent material, e.g., silicon oxide layer (SiO₂) or silicon nitride layer (SiNₓ).

The first insulating layer 130 may overlap only a portion of the connecting pattern 124. For example, edges of the connecting pattern 124, i.e., a part contacting the first sensing cell 122, may not be overlapped by the first insulating layer 130. On this account, the connecting pattern 124 and the first sensing cells 122 may be electrically connected without a separate contact hole.

However, as the connecting pattern 124 and the metal pattern 160 are implemented as low-resistive metal, e.g., Al, AlNd, Mo, Cu, and the like, the low-resistive metal may exhibit a high reflectivity of external light. In detail, the low-resistive metal may exhibit a very high reflectivity of external light, as compared to the transparent conductive material, e.g., ITO, in the first and second sensing cells 122, 142. For example, when the connecting pattern 124 is implemented as a low-resistive metal, e.g., Mo, the reflectivity of the external light may be about 90%, as compared to reflectivity of about 10% when a connecting pattern is made of a transparent conductive material, e.g., ITO. Further, the connecting pattern 124 may be visible to a user due to the external light reflectivity difference between the connecting pattern 124 and the first and second sensing cells 122, 142 formed adjacent to each other, i.e., when the connecting pattern 124 is implemented as an opaque low-resistive metal.

Therefore, according to an embodiment, a second insulating layer 170 may be formed on the first insulating layer 130. The second insulating layer 170 may be colored, and may absorb the external light formed in a region overlapping the connecting pattern 124. For example, the second insulating layer 170 may overlap the connecting pattern 124, e.g., completely overlap an entire exposed surface of the connecting pattern 124. For example, the second insulating layer 170 may cover exposed surfaces of the connecting pattern 124, e.g., the second insulating layer 170 may completely overlap at least three surfaces of the connecting pattern 124. For example, the second insulating layer 170 may contact the connecting pattern 124 and the first sensing cells 122.

For example, the second insulating layer 170 may be implemented through a colored photoresist, e.g., photoresist of a dark color. The colored photoresist, e.g., black photoresist, may absorb the incident light, so that reflectivity of the external light may be substantially reduced by forming the second insulating layer 170 in an upper portion of the connecting pattern 124.

In addition, the photoresist may perform as an insulating layer. Therefore, the second insulating layer 170 implemented as the colored photoresist may also be formed in a region intersecting, e.g., overlapping, the metal pattern 160. In this case, if the metal pattern 160 has a high reflectivity of the external light, the high reflectivity of the external light may be prevented or substantially minimized by implementing the second insulating layer 170 on the region intersecting the metal pattern 160, e.g., as opposed to a transparent insulating layer. For example, as illustrated in FIGS. 1 and 2, the second insulating layer 170 may completely cover the metal pattern 160. In addition, a separate mask process for forming an insulating layer on the metal pattern 160 may not be needed because the second insulating layer 170 may be formed through a same mask process, e.g., simultaneously, on the metal pattern 160 and the connecting pattern 124.

As further illustrated in FIG. 1, a pad unit 164 may be positioned in the display area 100, and may contact a flexible printed circuit (FPC) in order to supply the signal to the driving circuit (not shown). As further illustrated in FIG. 1, the pad unit 164 may be exposed outside the second insulating layer 170. The pad unit 164 may be formed of a same material as the first and second sensing cells 122, 142.

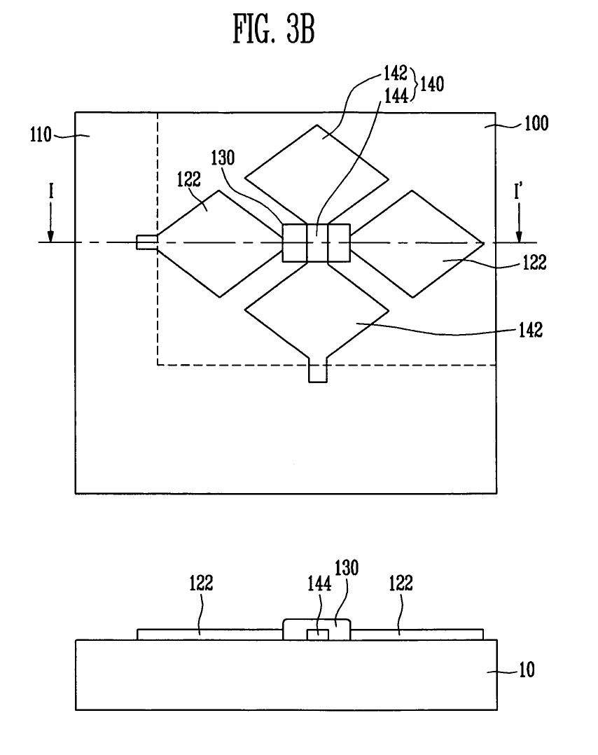

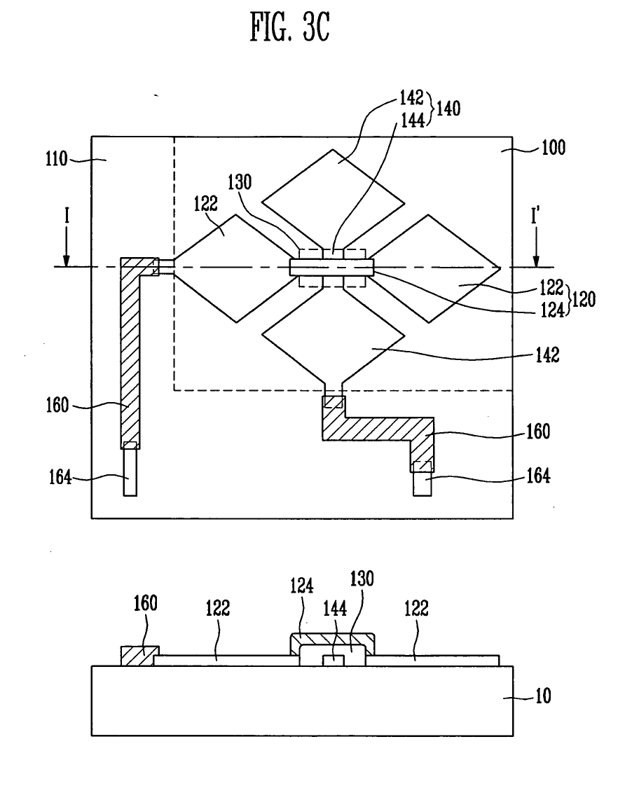

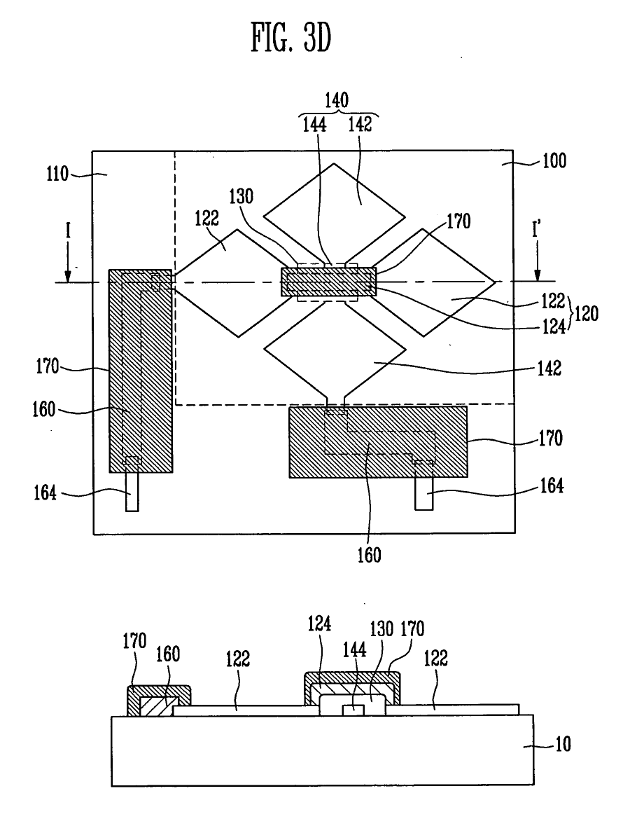

FIG. 3A to 3D illustrate plan views and cross-sectional views of stages in a method for manufacturing a touch screen panel according to an embodiment. It is noted that 2×2 second sensing cells disposed at the end of one side of the display region 100 among the first and the second sensing patterns arranged on the display region 100 will be described as an example.

Referring to FIG. 3A, the first sensing cells 122 and the second sensing cells 142 may be formed on the display region 100 of the transparent substrate 10. Adjacent second sensing cells 142 may be connected to each other via the connecting unit 144.

The first sensing cells 122 and the second sensing cells 142 may be formed in the same layer during the same process. The first and second sensing cells 122, 142 may be implemented as a transparent conductive material, e.g., ITO, for implementing the movement of the touch screen panel. As the sensing cells disposed in the X direction and the Y direction should be electrically connected, the first sensing cells 122 and the second sensing cells 142 may perform a role of a sensing electrode. Accordingly, the second sensing cells 142 may be electrically connected to each other by the connecting unit 144, and the first sensing cells 122 may be electrically connected to each other by the connecting pattern 124 formed at a later stage.

The connecting unit 144 may be formed as a unified body with the second sensing cells 142, and the adjacent second sensing cells 142 may all be connected through the connecting unit 144. In other words, the connecting unit 144 may be formed in the same layer through the same process, e.g., by using the same transparent conductive material, as the second sensing cells 142.

As further illustrated in FIG. 3A, the non-display region 110 may be defined in an edge portion of the display region 100, and metal patterns (not shown) electrically connected to the first sensing cells 122 and the second sensing cells 142 disposed in the end of the display region 100 may be formed in the non-display region 110. In this case, the metal patterns may supply the signal sensed in the sensing cells to the driving circuit (not shown).

For example, the FPC (not shown) may be implemented via a connection to the pad unit 164 in order to connect between the driving circuit and the metal patterns, so the pad unit 164 may be formed at each end of the metal patterns. In an embodiment, the pad unit 164 may be formed through a same process by using a same material as the first and the second sensing cells 122, 142.

As illustrated in FIG. 3B, the first insulating layer 130, e.g., having an island shape, may be formed to overlap the connecting unit 144. For example, the first insulating layer 130 may completely overlap the connecting unit 144 and fill spaces between the connecting unit 144 and the first sensing cells 122.

The first insulating layer 130 may be formed in order to prevent a short between the connecting unit 144 and the connecting pattern 124 formed later. The first insulating layer 130 may be an inorganic insulating layer made of a transparent material, e.g., a silicon oxide layer (SiO₂) or a silicon nitride layer (SiNₓ).

It is noted that while the first insulating layer 130 is formed in a region between the first sensing cells 122, the first insulating layer 130 may not overlap edges of the first sensing cells 122. That is, the edges of the first sensing cells 122 may remain exposed to facilitate connection thereof to the connecting pattern 124 to be formed later on the first insulating layer 130 without separate contact holes.

Next, as illustrated in FIG. 3C, the connecting pattern 124, e.g., in a form of a bar, may be formed on the first insulating layer 130 along the first direction, e.g., along the X direction, to connect adjacent first sensing cells 122. The connecting pattern 124 may electrically connect the adjacent first sensing cells 122, e.g., both ends of the connecting pattern 124 may be projected around the first insulating layer 130 to contact the exposed edges of the first sensing cells 122.

In an embodiment, the connecting pattern 124 may be formed by using a low-resistive metal. The low-resistive metal, e.g., Al, AlNd, Mo, Cu, etc., may be disposed in the display region 100 to form the connecting pattern 124 connecting the first sensing cells 122 and in the non-display region 110 adjacent to the end of the display region 100 to form the metal pattern 160 that supplies the signal sensed by the sensing cells to the driving circuit (not shown). In this case, the connecting patterns 124 and the metal pattern 160 may be formed in the same layer through the same process. Therefore, a number of processes and overall manufacturing time may be reduced because an additional mask process that forms the connecting patterns 124 is not needed.

As mentioned above, a charge flow in the connecting portion of the first sensing cells 122 may be smooth. Therefore, the sensing sensitivity of the first sensing cells 122 may be improved by implementing the low-resistivity connecting pattern 124 that connects the first sensing cells 122, as opposed to a transparent conductive material.

In addition, the metal pattern 160 may be electrically connected to the first and/or second sensing cell disposed in the end of the display region 100, and may supply the signal sensed by the sensing cells 122, 142 to the driving circuit (not shown). An end of the metal pattern 160 may overlap with the pad unit 164, i.e., a unit formed of a transparent conductive material.

As the connecting pattern 124 and the metal pattern 160 are implemented of a low-resistive metal, which may exhibit high reflectivity of external light, an embodiment may include the second insulating layer 170, as illustrated in FIG. 3D. The second insulating layer 170 may absorb the external light, thereby reducing reflectivity and minimizing a visual difference between the connecting pattern 124 and the sensing cells.

The second insulating layer 170 may be formed on the connecting pattern 124 and on the metal pattern 160, e.g., completely overlap each of the connecting pattern 124 and the metal pattern 160, and may be implemented through a colored photoresist. For example, the second insulating layer 170 may be formed of a black photoresist, and may absorb incident light. Therefore, reflectivity of the external light may be substantially reduced by forming the second insulating layer 170 in an upper portion of the connecting pattern 124.

In addition, the photoresist of the second insulating layer 170 may perform as an insulating layer. Therefore, the second insulating layer 170 implemented as the colored photoresist may be formed on the metal pattern 160, thereby preventing or substantially minimizing high reflectivity of external light from the metal pattern 160. As such, a separate mask process for forming an insulating layer on the metal pattern 160 may be eliminated, as the insulating layer on the metal pattern 160 may be formed through the same mask process as the second insulating layer 170 on the connecting pattern 124.

According to example embodiments, a touch screen panel may include first and second sensing cells formed of a transparent conductive material on the same layer, a connecting pattern formed of a low-resistance metal and connecting the first or second sensing cells, and a colored photoresist on the connecting pattern. The colored photoresist may reduce reflectivity of the external light off of the connecting pattern. Accordingly, electrostatic vulnerability of the connecting pattern may be reduced. Further, electrostatic discharge (ESD) may be minimized and visibility of the connecting pattern by a user's eyes may be prevented or substantially minimized.

In contrast, when the first and second sensing patterns are disposed in different layers with an insulating layer therebetween, e.g., when the first sensing patterns are disposed in a bottom portion and the second sensing patterns are disposed in an upper portion of the layer, a sheet resistance of a transparent conductive material, e.g., ITO used for forming the sensing patterns, may be large. As such, a width of a corresponding connecting unit may be large, i.e., in order to reduce the sheet resistance, thereby increasing parasitic capacitance and reducing sensitivity of the sensing patterns.

Further, when conventional first and second sensing patterns are formed in the same layer, a connecting pattern formed of a low-resistance opaque metal or a transparent conductive material may be used. However, as a connecting pattern of a transparent conductive material may have a high resistance value, there may be a limit to reducing the width. Therefore, the parasitic capacitance generated in the intersection portion of the first and the second sensing cells may not be reduced. Furthermore, while a connecting pattern formed of a low-resistance opaque metal may have reduced parasitic capacitance in the intersection, e.g., by minimizing the width of the connecting pattern, the charge flow through the connecting pattern may concentrate in a narrow space, and the connecting patterns may be disposed in the upper portion of the insulating layer. Therefore, the connecting pattern may be vulnerable to electrostatic discharge.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A touch screen panel, comprising:
a plurality of first sensing cells arranged in a first direction and a plurality of second sensing cells arranged in a second direction on a display region of a transparent substrate;
a connecting unit connecting the second sensing cells to each other;
a connecting pattern connecting the first sensing cells to each other, the connecting pattern intersecting the connecting unit;
a first insulating layer between the connecting pattern and the connecting unit; and
a colored second insulating layer on the connecting pattern.

2. The touch screen panel as claimed in claim 1, wherein the first sensing cells, the second sensing cells, and the connecting unit include a transparent conductive material.

3. The touch screen panel as claimed in claim 1, wherein the connecting pattern includes a low-resistance metal.

4. The touch screen panel as claimed in claim 1, wherein the second insulating layer includes a colored photoresist.

5. The touch screen panel as claimed in claim 1, further comprising a metal pattern in a non-display region of the transparent substrate, the metal pattern being electrically connected to the first sensing cell and the second sensing cell.

6. The touch screen panel as claimed in claim 5, wherein the colored second insulating layer is on the metal pattern.

7. The touch screen panel as claimed in claim 1, wherein the connecting pattern is between the first insulating layer and the colored second insulating layer.

8. The touch screen panel as claimed in claim 1, wherein the colored second insulating layer covers exposed surfaces of the connecting pattern.

9. The touch screen panel as claimed in claim 8, wherein the colored second insulating layer completely overlaps at least three surfaces of the connecting pattern.

10. The touch screen panel as claimed in claim 1, wherein the colored second insulating layer contacts the connecting pattern and the first sensing cells.

11. A method for manufacturing a touch screen panel, comprising:
forming a plurality of first sensing cells arranged in a first direction and a plurality of second sensing cells arranged in a second direction on a display region of a transparent substrate;
forming a connecting unit connecting the second sensing cells to each other;
forming a connecting pattern connecting the first sensing cells to each other, such that the connecting pattern intersects the connecting unit;
forming a first insulating layer between the connecting pattern and the connecting unit; and
forming a colored second insulating layer on the connecting pattern.

12. The method for manufacturing the touch screen panel as claimed in claim 11, wherein the first sensing cells, the second sensing cells, and the connecting unit are formed of a transparent conductive material.

13. The method for manufacturing the touch screen panel as claimed in claim 11, wherein the connecting pattern is formed of a low-resistance metal.

14. The method for manufacturing the touch screen panel as claimed in claim 11, wherein the second insulating layer is formed of a colored photoresist.

15. The method for manufacturing the touch screen panel as claimed in claim 11, further comprising forming a metal pattern in a non-display region of the transparent substrate, such that the metal pattern is electrically connected to the first sensing cell and the second sensing cell.

16. The method for manufacturing the touch screen panel as claimed in claim 15, wherein the colored second insulating layer is formed on the metal pattern.
